(19) United States
(12) Patent Application Publication
(10) Pub. No.: US 2026/0152334 A1
(43) Pub. Date: Jun. 4, 2026

(54) METHOD FOR PRODUCING OPENING DETECTION SHEET, OPENING DETECTION SHEET, AND PACKAGING MATERIAL

(71) Applicants: UACJ FOIL CORPORATION, Tokyo (JP); UACJ CORPORATION, Tokyo (JP)

(72) Inventors: Hisaya Kato, Tokyo (JP); Takamichi Watanabe, Tokyo (JP)

(21) Appl. No.: 18/967,451

(22) Filed: Dec. 3, 2024

Related U.S. Application Data
(63) Continuation of application No. 17/611,626, now abandoned.

(30) Foreign Application Priority Data
May 17, 2019 (JP) 2019-094025

(51) Int. Cl. B65D 55/02; B41M 1/10; B41M 3/00; B41M 7/00; B65D 75/36; C09D 11/037; C09D 11/106; C09D 11/52; H05K 3/12

(52) U.S. Cl. CPC B65D 55/02; B41M 1/10; B41M 3/008; B41M 7/009; B65D 75/367; C09D 11/037; C09D 11/106; C09D 11/52; H05K 3/1275; H05K 2203/0104

(57) ABSTRACT

The present invention realizes an inexpensive packaging material having an opening detection function by simplifying the configuration of an opening detection sheet. The present invention includes: a metal foil layer; a first resin layer having an insulation property; and a second resin layer stacked on at least a part of the first resin layer, wherein a circuit pattern is printed on the first resin layer with use of conductive ink containing carbon nanotubes.

### CROSS-REFERENCE TO RELATED APPLICATIONS

This application is a continuation of U.S. patent application Ser. No. 17/611,626 filed Nov. 16, 2021, which is a U.S.C. § 371 national stage filing of International Application No. PCT/JP2020/019567 filed on May 18, 2020, which claims priority to Japanese Patent Application No. 2019-094025 filed on May 17, 2019. The entire contents of each of the aforementioned applications are incorporated herein by reference.

### TECHNICAL FIELD

The present invention relates to an opening detection sheet, an opening detection device including the opening detection sheet, a control program, and a method for producing the opening detection sheet.

### BACKGROUND ART

Conventionally, in a packaging material for storing, for example, tablets and foods in storing parts (for example, blister package), a technique for detecting the opening of the storing parts is known. For example, an opening detection sheet disclosed in Patent Literature 1 has a circuit layer including a plurality of conducting wires, and each of the plurality of conducting wires is formed so as to be broken by opening of a corresponding target part among a plurality of target parts which are targeted for detection of opening.

In a case where the stored object such as a tablet and food is taken out from the storing part, the sheet constituting the storing part is broken. In the case of a blister package in which the opening detection sheet described in Patent Literature 1 is employed for the storing part, it is configured such that the conducting wire of the circuit layer of the opening detection sheet is broken when the opening detection sheet is opened. When the conducting wire is broken, an electrical signal generated in the circuit layer changes. The opening detection sheet can detect that a tablet, food, and the like have been taken out from the storing part on the basis of breakage of the conducting wire included in the circuit layer. Note that examples of the change that occurs on the electrical signal in the circuit layer include a change in a current value detected upon application of a voltage.

### CITATION LIST

### Patent Literature

### [Patent Literature 1]

Japanese Patent Application Publication Tokukai No. 2013-166590 (publication date: Aug. 29, 2013)

### SUMMARY OF INVENTION

### Technical Problem

FIG. 9 is a view illustrating an example of a cross section of a general opening detection sheet 90. (a) of FIG. 9 illustrates a cross section of a portion where a storing part 96 is not arranged, and (b) of FIG. 9 illustrates a cross section of a portion where the storing part 96 is arranged. Note that FIG. 9 illustrates the opening detection sheet 90 attached to a storage sheet 95 that forms the storing part 96.

The opening detection sheet 90 is configured such that an aluminum foil layer 94, an insulating layer 93, a circuit layer 92, and a polyethylene terephthalate (PET) sheet 91 are stacked. In the opening detection sheet 90, the aluminum foil layer 94 is attached to the surface of the storing sheet 95, which forms the storing part 96, on the side where a stored object 97 is pushed out. Note that an aluminum alloy foil may be used for the aluminum foil layer 94.

The circuit layer 92 includes conducting wires of a circuit pattern that is adapted to the arrangement of the storing part 96. In a case where the stored object 97 stored in the storing part 96 is taken out, the opening detection sheet 90 of the portion constituting the storing part 96 is broken, and a portion of the conducting wire included in the circuit layer 92 is broken. The opening detection sheet 90 is configured to detect whether or not the storing part 96 has been opened on the basis of whether or not the conducting wire included in the circuit layer 92 has been broken.

Conventionally, the conducting wire included in the circuit layer 92 is formed by etching an aluminum foil. A common etching process is performed in the following steps (1) to (4):
(1) a step of bonding an aluminum foil to a base material such as polyester film;
(2) a step of performing printing with a resist ink according to a circuit pattern and performing patterning;
(3) a step of etching with acid or the like; and
(4) a step of removing the resist ink with alkali or the like.

Etching is a complicated and extensive processing method. Energy consumption of etching is inevitable because treatments such as heating, drying, and UV irradiation are required in each step of etching. Further, since acid waste liquid is generated in the above step (3) and alkaline waste liquid is generated in the step (4), energy must be consumed for the treatment of these waste liquids. Thus, a packaging material in which the opening detection sheet produced by etching is employed cannot avoid a significant cost increase as compared with a packaging material not having the opening detection function.

Meanwhile, it is also possible to form the circuit layer 92 by printing a circuit pattern that is adapted to the arrangement of the storing part 96 on an aluminum foil with use of a metal paste such as silver paste. According to this method, an opening detection sheet can be produced without using an etching process. However, since the metal paste is expensive, an increase in cost of the packaging material in which the opening detection sheet is employed is inevitable.

It is an object of an aspect of the present invention to provide an opening detection sheet that achieves a reduced number of steps for producing the opening detection sheet by simplifying the configuration of the opening detection sheet, and realize an inexpensive packaging material.

### Solution to Problem

In order to solve the above problems, an opening detection sheet in accordance with an aspect of the present invention includes: a metal foil layer being made of a metal containing aluminum; a first resin layer having an insulation property; a circuit pattern being printed with use of an ink containing a conductive substance; and a second resin layer covering at least a part of the circuit pattern, wherein the metal foil layer, the first resin layer, the circuit pattern, and the second resin layer are stacked in this order.

An opening detection device in accordance with an aspect of the present invention is an opening detection device for detecting that a storing part which is one of storing parts has been opened in a packaging material, the opening detection device including: a terminal section being electrically connectable to a circuit pattern included in an opening detection sheet; and an opening detection processing section that detects breakage of the circuit pattern on a basis of a change having occurred on an electrical signal in the circuit pattern.

A method for producing an opening detection sheet in accordance with an aspect of the present invention includes: a first resin applying step of applying a first resin having an insulation property onto a metal foil layer being made of a metal containing aluminum to form a first resin layer; a circuit pattern printing step of printing, on the first resin layer, a circuit pattern with use of an ink containing a conductive substance; and a second resin applying step of applying a second resin so as to cover at least a part of the circuit pattern to form a second resin layer.

### Advantageous Effects of Invention

According to an aspect of the present invention, it is possible to provide an opening detection sheet that achieves a reduced number of steps for producing the opening detection sheet by simplifying the configuration of the opening detection sheet, and realize an inexpensive packaging material.

### BRIEF DESCRIPTION OF DRAWINGS

FIG. 1 is a cross-sectional view illustrating the configuration of a packaging material in which an opening detection sheet in accordance with an embodiment of the present invention is employed.

FIG. 2 is a view illustrating an example of an appearance of the packaging material.

FIG. 3 is a flowchart showing an example of a method for producing the opening detection sheet.
(a) of FIG. 4 is an external view illustrating a state in which the packaging material employing the opening detection sheet is attached to the opening detection device, and (b) of FIG. 4 is a view illustrating an appearance of the opening detection device when viewed from the side where a terminal section is provided.

FIG. 5 is a block diagram illustrating a configuration example of an opening detection device in accordance with an embodiment of the present invention.

FIG. 6 is a view illustrating an example of an opening detection result displayed on a display section 25 of the opening detection device.

FIG. 7 is a block diagram illustrating another configuration example of the opening detection device.

FIG. 8 is a view illustrating an example of an opening detection result displayed on an external device.

FIG. 9 is a view illustrating an example of a cross section of a general opening detection sheet, wherein (a) of FIG. 9 illustrates a cross section of a portion where a storing part is not arranged, and (b) of FIG. 9 illustrates a cross section of a portion where the storing part is arranged.

### DETAILED DESCRIPTION

### Embodiment 1

The following description will discuss an embodiment of the present invention in detail.

### (Configuration of Opening Detection Sheet 10)

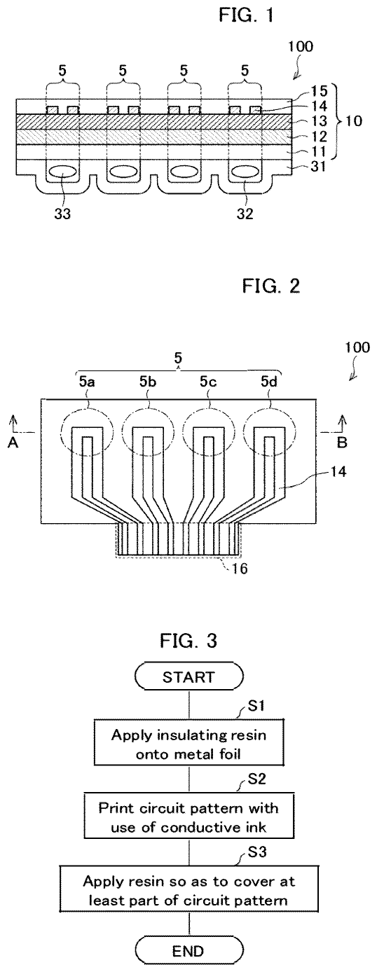

First, the configuration of an opening detection sheet 10 in accordance with the present invention will be described with reference to FIG. 1. FIG. 1 is a cross-sectional view illustrating the configuration of a packaging material 100 in which the opening detection sheet 10 in accordance with an embodiment of the present invention is employed. As illustrated in FIG. 1, the opening detection sheet 10 forms a storing part(s) 32, which is a space(s) for storing a stored object(s) 33 such as a medicine and food, by being bonded to a storage sheet 31 having one or more recesses.

The opening detection sheet 10 includes a metal foil layer 12, a first resin layer 13, a circuit pattern 14, and a second resin layer 15. Note that FIG. 1 illustrates the opening detection sheet 10 including a third resin layer 11 that has thermal fusibility and is disposed on a surface of the metal foil layer 12 which surface faces away from the first resin layer 13. The third resin layer 11 is a layer that is provided to thermally fuse the opening detection sheet 10 and the storage sheet 31 to each other.

The metal foil layer 12 is a layer made of a metal. Examples of the metal used for the metal foil layer 12 include aluminum, an aluminum alloy, and the like. Here, the aluminum contains aluminum (Al) and unavoidable impurities. The aluminum alloy is intended to be an aluminum alloy that contains not only aluminum (Al) and unavoidable impurities, but also iron (Fe): 0.10 mass % to 0.60 mass % (hereinafter, mass % is simply referred to as %), silicon (Si): 0.01% to 0.50%, and copper (Cu): 0.01% to 0.20%. For example, as the metal foil layer 12, Japanese Industrial Standards (JIS) IN30 hard aluminum foil can be used. Surfaces of this aluminum foil may be bright surfaces or may be matte surfaces. The following description will discuss, in one example, a case where an aluminum foil having one surface which is a bright surface and another surface which is a matte (so-called frosted) surface (third surface) is used as an example. Note that the thickness of the metal foil (that is, the thickness of the metal foil layer 12) is a thickness that achieves the opening detection sheet 10 which stably stores the stored object 33 and can be easily broken when the stored object 33 is taken out, and may be, for example, 15 μm to 20 μm.

The first resin layer 13 is stacked on the metal foil layer 12 and has an insulation property. The first resin layer 13 can be formed by applying an insulating resin (first resin) onto the metal foil layer 12. A dry weight per unit area of the first resin layer 13 is preferably not less than 1.48 g/m² and not more than 3.70 g/m². For example, in a case where the dry weight per unit area of the first resin layer 13 is less than 1.48 g/m², the first resin layer 13 becomes thin and thus may fail to maintain a sufficient thickness as an insulating layer when, for example, heat (for example, 140° C.) and pressure (for example, 0.25 MPa) are applied for thermally fusing the opening detection sheet 10 and the storage sheet 31 to each other. On the other hand, increasing the thickness of the first resin layer 13 by causing the first resin layer 13 to have the dry weight per unit area of greater than 3.70 g/m², leads to an improvement in insulation property, but leads to an increase in cost because making the first resin layer 13 thicker than necessary increases the amount of resin used. In the case of a step of applying the insulating resin, performing this step twice achieves the application for the dry weight per unit area of up to not more than 3.70 g/m². Therefore, in order to apply a thicker coating to achieve the first resin layer 13 having the dry weight per unit area of more than 3.7 g/m², it is necessary to repeat the step of applying the insulating resin, for example, three or more times. This increases the number of steps for producing the opening detection sheet 10.

As the resin having an insulation property used for the first resin layer 13, a resin containing vinyl chloride, vinyl acetate, or the like as a main component can be used. One surface (first surface) of the first resin layer 13 is in contact with the bright surface of the metal foil layer 12. Note that on another surface (second surface) of the first resin layer 13, the circuit pattern 14 is printed with use of conductive ink which contains a conductive substance.

The circuit pattern 14 is formed by applying an ink containing a conductive substance onto the first resin layer 13. The conductive ink used for forming the circuit pattern 14 is an ink containing a pigment, a resin, a conductive substance, a solvent, and the like. The pigment may be, but is not limited to, a pigment containing, for example, carbon particles (so-called carbon black). In this case, the circuit pattern 14 is shown as a black line printed on the opening detection sheet 10.

The conductive ink may contain carbon nanotubes as the conductive substance. It is known that a conductive ink in which carbon nanotubes are included and dispersed has improved electrical conduction property. The electrical conductivity of the circuit pattern 14 can be adjusted by adjusting, for example, the concentration of the conductive ink used to form the circuit pattern 14, the amount of the conductive ink applied, and the amount of the carbon nanotubes added.

The second resin layer 15 is stacked so as to cover at least a part of the circuit pattern 14. In other words, the second resin layer 15 is stacked on at least a part of a surface (second surface) of the circuit pattern 14 which surface faces away from the first resin layer 13 and the metal foil layer 12. As a result, the first resin layer 13 has: a first region that has the circuit pattern 14 which is covered with the second resin layer 15; and a second region that has the circuit pattern 14 which is not covered with the second resin layer 15. The second resin layer 15 is formed by applying a resin (second resin) so as to cover at least a part of the circuit pattern 14.

The second resin layer 15 may be, for example, a resin layer containing an epoxy resin as a main component. The dry weight per unit area of the second resin layer 15 is preferably not less than 0.8 g/m² and not more than 2.0 g/m², and more preferably not less than 1.0 g/m² and not more than 1.8 g/m². In a case where the dry weight per unit area of the second resin layer 15 is less than 0.8 g/m², the second resin layer 15 becomes thin, and the opening detection sheet 10 fails to achieve sufficient heat resistance which is required to withstand heat and the like applied, for example, when the opening detection sheet 10 is thermally fused to the packaging material 100 (described later). In a case where the opening detection sheet 10 fails to achieve sufficient heat resistance, the conductive ink may flow out of the circuit pattern 14. On the other hand, in a case where the dry weight per unit area of the second resin layer 15 exceeds 2.0 g/m², the second resin layer 15 becomes thick. This leads to deterioration in property of conduction of heat which is applied for processing and molding the opening detection sheet 10. Making the second resin layer 15 thicker than necessary increases the amount of resin used and thus results in an increase in cost. Further, the deterioration in thermal conduction property increases energy which is required for processing and molding the opening detection sheet 10.

Note that the opening detection sheet 10 illustrated in FIG. 1 includes, not only the above-described members, but also a third resin layer 11 which is stacked on a third surface, which faces away from the first surface, of the metal foil layer 12. The third resin layer 11 is a layer that is provided for use in thermally fusing the opening detection sheet 10 to another member (for example, the storage sheet 31).

The third resin layer 11 can be formed by applying a thermally fusible resin onto the metal foil layer 12. The conditions under which the opening detection sheet 10 is thermally fused to the packaging material 100 are changed as appropriate depending on a resin used for the third resin layer 11, but may be typically a temperature of 140° C. and a pressure of 0.25 MPa.

Note that the opening detection sheet 10 may be bonded to another member by another method (for example, with glue or the like). Since the opening detection sheet 10 can be suitably used in any situation where the opening detection function is desired to be introduced, the opening detection sheet 10 may be employed without being bonded to any member.

### (Packaging Material 100)

Next, the packaging material 100 will be described. As illustrated in FIG. 1, the packaging material 100 includes the opening detection sheet 10 and includes a storing part(s) 32 that store(s) the stored object(s) 33. The packaging material 100 is configured such that the stored object(s) 33 is/are taken out from the storing part 32 when the opening detection sheet 10 is broken.

The opening detection sheet 10 is arranged on the storing part(s) 32, which store(s) the stored object(s) 33, so as to seal respective openings of the recesses of the storage sheet 31 therewith. The packaging material 100 having such a configuration has a function of detecting that the stored object 33 has been taken out. Here, a polyvinyl chloride (PVC) film can be employed as the storage sheet 31.

Note that although FIG. 1 illustrates the packaging material 100 which employs the storage sheet 31, the present invention is not limited to such a packaging material. For example, the packaging material 100 may be a packaging material in which the storing part(s) 32 is/are configured such that the stored object(s) 33 is/are surrounded by a plate-shaped or sheet-shaped member and the opening detection sheet 10. Alternatively, the packaging material 100 may be a packaging material in which the storing part(s) 32 is/are formed only by the opening detection sheet 10. That is, the storage sheet 31 is not an essential component of the packaging material 100.

### <Detection Target Area 5>

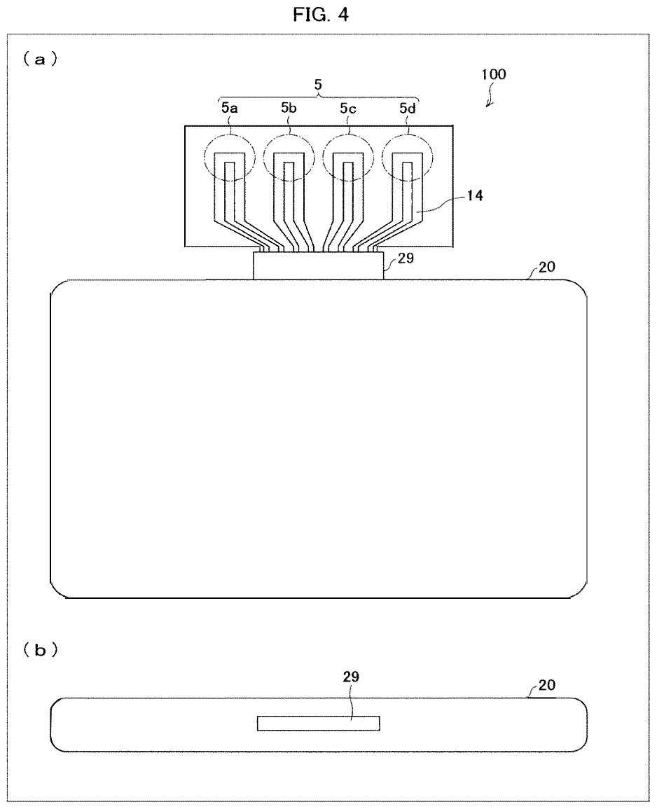

Next, a detection target area(s) 5 which is/are a target(s) for detection of opening by the opening detection sheet 10 will be described with reference to FIG. 2. FIG. 2 is a view illustrating an example of an appearance of the packaging material 100 when viewed from the side where the first resin layer 13 and the second resin layer 15 are provided.

In the opening detection sheet 10, the detection target area(s) 5 is/are set, and the circuit pattern 14 is arranged so as to be broken when the opening detection sheet 10 is broken in the detection target area 5. FIG. 2 is a view illustrating the packaging material 100 having four detection target areas 5a to 5d. The packaging material 100 illustrated in FIG. 2 can package, for example, once-a-day tablets for four days.

As illustrated in FIG. 1, in the packaging material 100, the circuit pattern 14 of the opening detection sheet 10 has separate parts corresponding one-to-one to the storing parts 32 that store the stored objects 33. That is, the circuit pattern 14 has separate parts corresponding one-to-one to the detection target areas 5, and the separate parts are not electrically conductive with each other. For example, when the opening detection sheet 10 is broken in the detection target area 5a of the packaging material 100 illustrated in FIG. 2, the circuit pattern 14 arranged in the detection target area 5a is broken, but the circuit pattern 14 arranged in the other detection target areas 5b to 5d are not broken.

When the opening detection sheet 10 is broken in a certain detection target area 5, a change occurs on an electrical signal in the circuit pattern 14. For example, in a case where a predetermined voltage is applied to the circuit pattern 14 arranged in each detection target area 5, a change in the current value is detected in the broken circuit pattern 14. By connecting the packaging material 100 having such a configuration to an opening detection device 20 (described later), it is possible to realize the opening detection function of detecting whether or not the opening detection sheet 10 in the detection target area 5 has been broken.

Note that the number of detection target areas 5 included in the packaging material 100 can be changed as appropriate according to the number of tablets taken by a user, and is not limited to four. For example, a packaging material 100 having seven detection target areas 5 (not illustrated) can package once-a-day tablets for one week.

### <Connecting Section 16>

As illustrated in FIG. 2, the circuit pattern 14 of the opening detection sheet 10 employed in the packaging material 100 is provided with a connecting section 16 that is not covered with the second resin layer 15. A terminal section 29 of the opening detection devices 20 and 20a (described later) and the opening detection sheet 10 of the packaging material 100, while in contact with each other at the connecting section 16, are connected to each other so as to be electrically conductive with each other. Note that the position where the connecting section 16 is provided can be changed as appropriate according to the shape and position of the terminal section 29 of the opening detection devices 20 and 20a.

### (Method for Producing Opening Detection Sheet 10)

Next, a method for producing the opening detection sheet 10 including the metal foil layer 12, the first resin layer 13, the circuit pattern 14, and the second resin layer 15 will be described with reference to FIG. 3. FIG. 3 is a flowchart showing an example of the method for producing the opening detection sheet 10.

First, the insulating resin is applied onto the whole of one-side surface of an aluminum foil or an aluminum alloy foil used for the metal foil layer 12 to form the first resin layer 13 (step S1: first resin applying step). In step S1, gravure printing or the like method can be employed.

Next, the circuit pattern 14 is printed on the first resin layer 13, which has been formed in step S1, using the conductive ink (step S2: circuit pattern printing step). As a method of printing the circuit pattern 14, gravure printing can also be employed.

Next, the second resin is applied so as to cover at least a part of the circuit pattern 14, which has been printed in step S2, to form the second resin layer 15 (step S3: second resin applying step). In step S3, gravure printing or the like method can also be employed.

Note that in a case where the third resin layer 11 is further provided on the opening detection sheet 10, gravure printing or the like method can also be employed as in steps S1 to S3 (third resin applying step).

Here, the gravure printing is a type of intaglio printing which is used for printing on a metal foil, a film, etc. For example, the application of the resin in steps S1 and S3 is mainly carried out in a process as indicated in (1) to (5) below.
(1) A gravure printing cylinder provided with recesses on a plate surface thereof is partially immersed in a reservoir of a resin to be applied onto the metal foil used for the metal foil layer 12, so that the recesses on the plate surface are filled with the resin. By adjusting the depth of the recesses provided on the plate surface of the gravure printing cylinder, it is possible to adjust the thickness of the resin to be applied, the dry weight thereof, and the like.
(2) While being rotated, the gravure printing cylinder is lifted from the resin reservoir.
(3) The resin adhering to areas other than the recesses on the plate surface of the gravure printing cylinder is removed with a doctor blade.
(4) The metal foil is passed between a pressure roller and the gravure printing cylinder, so that the resin in the recesses on the plate surface of the gravure printing cylinder is transferred to the metal foil.
(5) After drying, the process proceeds to the next process.

In step S2, the conductive ink is used instead of the resin. That is, resin layers included in the opening detection sheet 10 and the circuit pattern 14 can all be formed by using the same equipment (for example, gravure printing equipment).

As discussed above, in the method for producing the opening detection sheet 10 in accordance with the present invention, the circuit pattern 14 is also formed by the same method as that of the formation of the first resin layer 13 and the second resin layer 15. The opening detection sheet 10 produced by such a method can keep the production cost low as compared with the conventional one produced by etching or the like. By employing the opening detection sheet 10, it is possible to realize a packaging material and the like having the opening detection function at a lower cost.

### Embodiment 2

The following description will discuss, with reference to FIGS. 4 to 6, the opening detection device 20 for detecting that the storing part 32 which stores the stored object 33 has been opened in the packaging material 100 in which the opening detection sheet 10 in accordance with the present invention is employed. For convenience of description, members having functions identical to those described in Embodiment 1 are assigned identical referential numerals, and their descriptions are omitted here.

### (Appearance of Opening Detection Device 20)

(a) of FIG. 4 is an external view illustrating a state in which the packaging material 100 illustrated in FIG. 2 is attached to the opening detection device 20. (b) of FIG. 4 is a view illustrating an appearance of the opening detection device 20 when viewed from the side where the terminal section 29 is provided.

As illustrated in FIG. 4, the terminal section 29 of the opening detection device 20 and the opening detection sheet 10 of the packaging material 100, while in contact with each other at the connecting section 16 illustrated in FIG. 2, are connected to each other so as to be electrically conductive with each other.

### (Configuration of Opening Detection Device 20)

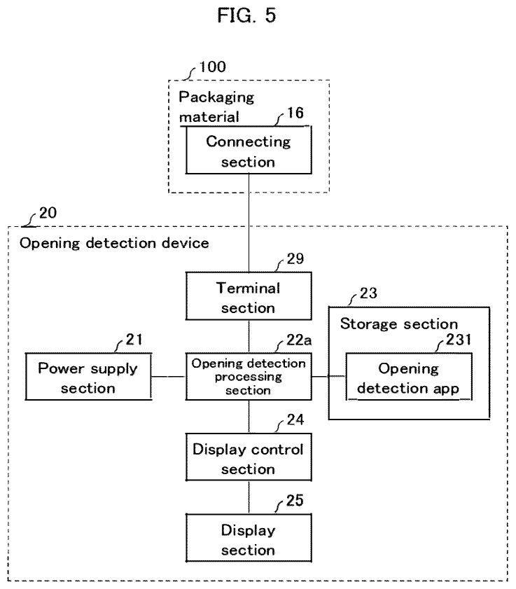

Next, the configuration of the opening detection device 20 will be described with reference to FIG. 5. FIG. 5 is a block diagram illustrating a configuration example of the opening detection device 20.

The opening detection device 20 includes the terminal section 29, a power supply section 21, an opening detection processing section 22a, a storage section 23, a display control section 24, and a display section 25.

The terminal section 29 is a terminal for, while in contact with the connecting section 16 of the circuit pattern 14 printed on the opening detection sheet 10 of the packaging material 100, electrically conducting the opening detection device 20 and the circuit pattern 14 of the packaging material 100.

The power supply section 21 is a battery, a battery cell, or the like, and supplies electric power required to execute each function of the opening detection device 20 to each section of the opening detection device 20. Further, a part of the electric power supplied from the power supply section 21 is supplied with a voltage applied by the opening detection processing section 22a to the circuit pattern 14 of the opening detection sheet 10 which is connected to the terminal section 29.

The opening detection processing section 22a detects the breakage of the circuit pattern 14 on the basis of a change having occurred on the electrical signal in the circuit pattern 14. More specifically, the opening detection processing section 22a applies a predetermined voltage to the circuit pattern 14 which is arranged in each detection target area 5 of the packaging material 100 connected to the terminal section 29, and measures a current value which is detected at that time. The opening detection processing section 22a detects the breakage of the individual circuit pattern 14 arranged in the detection target area 5, on the basis of whether or not the measured current value is equal to or higher than a preset current value.

Further, the opening detection processing section 22a collects, for each storing part 32, information such as which storing part 32 of the packaging material 100 has been opened and a date and time when opening of each storing section 32 was first detected. Note that a configuration may be employed in which the information collected by the opening detection processing section 22a is held in the storage section 23 until the opening detection sheet 10 connected to the opening detection device 20 is replaced.

Further, the opening detection processing section 22a reads an opening detection app 231 from the storage section 23, and generates a screen or the like to be displayed on the display section 25 on the basis of the collected information. Here, the opening detection app 231 is an application program for the opening detection processing section 22a executing a process for generating a display content for notifying the user of the opening status of each storing part 32.

The display control section 24 controls the display section 25 so that the display content generated by the opening detection processing section 22a is displayed on the display section 25. Note that the display control section 24 may be configured to read information collected in the past by the opening detection processing section 22a from the storage section 23 and display the information on the display section 25.

The display section 25 may be a thin flat panel, such as a liquid crystal display (LCD), a plasma display panel (PDP), or an organic EL (organic LED), which displays a character string and the like indicated by an image or text data. Further, the display section 25 may be configured such that a touch panel (not illustrated) is superimposed on the display section 25 so that the position where a touch operation has been performed by the user, the type of gesture, and the like are detected.

Note that the configuration in which the opening detection device 20 includes the display section 25 is described here as an example, but the present invention is not limited to this configuration. For example, a configuration may be employed in which the display content is transmitted to a display device (not illustrated) such as an external display having a larger screen and is displayed on the display. This makes it possible to display the opening status of the storing part 32 (see FIG. 1) in a large size and thus improves convenience of the user.

According to the above configuration, the opening detection device 20 detects the breakage of the circuit pattern 14 on the basis of a change having occurred on the electrical signal in the circuit pattern 14, and detects that the storing part 32 of the packaging material 100 has been opened. Further, in a case where the opening detection processing section 22a has detected the breakage of the circuit pattern 14, the opening detection device 20 outputs, for each storing part 32, information indicating that the detection target area 5 (corresponding to the storing part 32) in which the broken circuit pattern 14 is arranged has been opened.

### (Output Example of Detection Result)

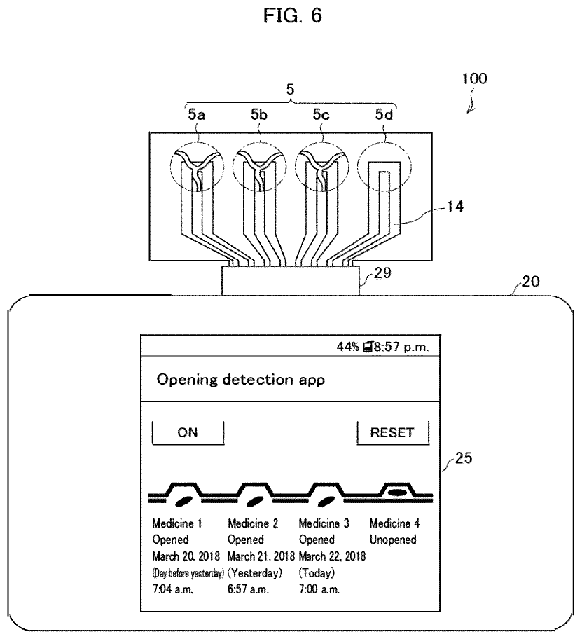

FIG. 6 is a view illustrating an example of the opening status displayed on the opening detection device 20. In FIG. 6, the packaging material 100 illustrated in FIG. 2 is connected to the opening detection device 20. Note that FIG. 6 illustrates an example in which the opening detection sheet 10 arranged in the detection target areas 5a to 5c (each corresponding to the storing part 32) of the packaging material 100 has been broken, and an opening detection result in the state in which the circuit pattern 14 in the detection target areas 5a to 5c is broken is displayed.

As illustrated in FIG. 6, displayed on the display section 25 of the opening detection device 20 are information indicating the opening status of each storing part 32 and information indicating when opening has been detected. In FIG. 6, “Opened” and “Unopened” are information indicating the opening status. Further, in FIG. 6, “Mar. 20, 2018”, “(Day before yesterday)”, “7:04 a.m.” and the like are information indicating when opening was carried out.

Note that the output of the opening status is not limited to displaying a content including a character string on the display section 25. For example, a configuration may be employed in which lights of different colors are illuminated for an opened state and an unopened state, or a configuration may be employed in which a voice indicating the storing part 32 to be opened is outputted by voice from a speaker or the like.

By displaying such information, the opening detection device 20 can allow the user to appropriately check the opening status of each storing part 32. By using the opening detection device 20 and the packaging material 100, in one example, it is possible to appropriately prevent a user from forgetting to take a medicine to be taken at a fixed timing every day, or to prevent the user from mistakenly taking a medicine to be taken at a predetermined interval at a short interval.

### Embodiment 3

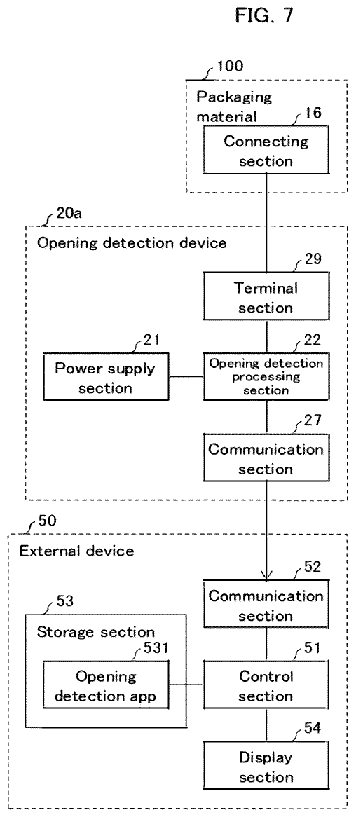

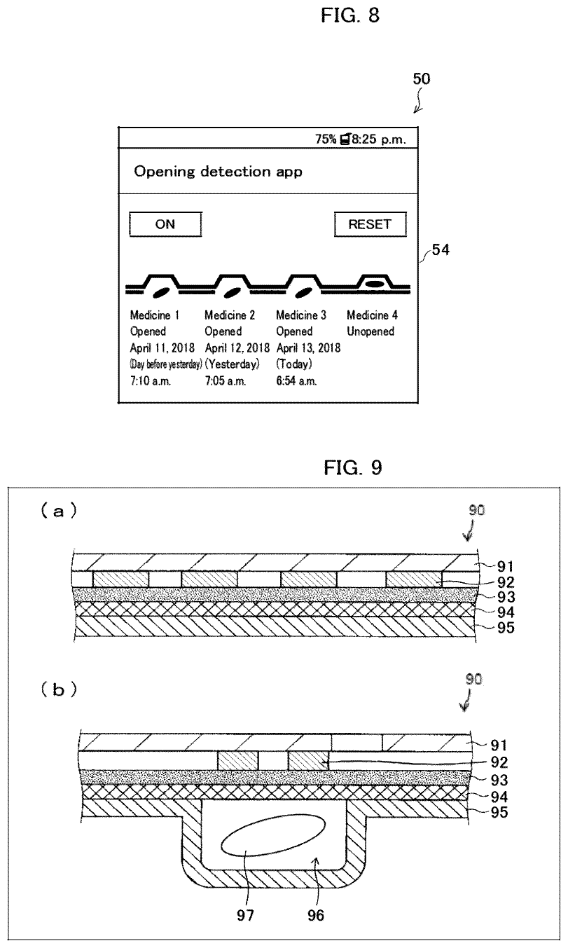

The following description will discuss, with reference to FIGS. 7 and 8, the opening detection device 20a having a function of detecting that the storing part 32 of the packaging material 100 in which the opening detection sheet 10 in accordance with the present invention is employed has been opened and transmitting a result of the detection to an external device 50. For convenience of description, members having functions identical to those described in Embodiments 1 and 2 are assigned identical referential numerals, and their descriptions are omitted here.

### (Configuration of Opening Detection Device 20a)

FIG. 7 is a block diagram illustrating a configuration example of the opening detection device 20a. Note that FIG. 7 also illustrates a main configuration of the external device 50 that is communicably connected to the opening detection device 20a. The opening detection device 20a further includes a communication section 27 that transmits, to the external device 50, a detection result (for example, information indicating the opening status of the storing part 32 corresponding to the detection target area 5) obtained by the opening detection processing section 22. Here, the opening detection processing section 22 may execute the same process as that executed by the opening detection processing section 22a which is included in the opening detection device 20 illustrated in FIG. 5. The external device 50 includes a control section 51 that causes a display section 54 to display information indicating that the storing part 32 corresponding to the detection target area 5 in which the circuit pattern 14 is arranged has been opened. Note that although the opening detection device 20a illustrated in FIG. 7 does not include the display section 25 or the like, the present invention is not limited to such a configuration, and the opening detection device 20a may be configured to include the display section 25 as in the opening detection device 20 illustrated in FIG. 5.

### (Configuration of External Device 50)

The external device 50 is an electronic device that includes the display section 54 which displays information indicating that the storing part 32 has been opened. Examples of the external device 50 include a smartphone, a mobile phone, a tablet terminal, and the like. As illustrated in FIG. 7, the external device 50 includes a communication section 52, the control section 51, the display section 54, and a storage section 53. The external device 50 transmits and receives data to and from the opening detection device 20a via the communication section 52. Note that the opening detection device 20a and the external device 50 may be connected by wire or may be connected wirelessly. For the wireless connection, for example, Bluetooth (registered trademark) can be used.

The control section 51 is a CPU. The control section 51 reads an opening detection app 531 from the storage section 53, and generates a screen or the like to be displayed on the display section 54 on the basis of information having been received from the opening detection device 20a. Here, the opening detection app 531 is an application program for the control section 51 executing a process for generating a display for notifying the user of the opening status of each storing part 32.

The display section 54 may be a thin flat panel, such as a liquid crystal display (LCD), a plasma display panel (PDP), or an organic EL (organic LED), which displays a character string and the like indicated by an image or text data. Further, the display section 54 may be configured such that a touch panel (not illustrated) is superimposed on the display section 25 so that the position where a touch operation has been performed by the user, the type of gesture, and the like are detected.

### (Output Example of Detection Result)

FIG. 8 is a view illustrating an example of a case where the opening status is displayed by the external device 50 having received the detection result from the opening detection device 20a to which the packaging material 100 employing the opening detection sheet 10 illustrated in FIG. 2 has been connected. Note that FIG. 8, as in FIG. 6, illustrates an example in which the opening detection sheet 10 arranged in the detection target areas 5a to 5c (each corresponding to the storing part 32) of the packaging material 100 has been broken, and an opening detection result in the state in which the circuit pattern 14 in the detection target areas 5a to 5c is broken is displayed.

The control section 51 acquires information such as which storing part 32 of the packaging material 100 has been opened and a date and time when each storing part 32 has been opened from the opening detection device 20a via the communication section 52. Then, the control section 51 causes the display section 54 of the external device 50 to display, for example, information indicating the opening status (i.e., “opened” or “unopened”) of each storing part 32 and information indicating when opening has been detected.

According to this configuration, the opening detection device 20a transmits information indicating the opening status to the external device 50 so that the information is displayed on the external device 50. Thus, the opening detection device 20a only needs to have minimum necessary functions. Therefore, the cost for producing the opening detection device 20a can be kept low.

### [Software Implementation Example]

Control blocks of the opening detection devices 20 and 20a (particularly, the opening detection processing sections 22a and 22) and the control section 51 of the external device 50 can be realized by a logic circuit (hardware) provided in an integrated circuit (IC chip) or the like or can be alternatively realized by software.

In the latter case, the opening detection devices 20 and 20a and external device 50 include a computer that executes instructions of a program that is software realizing the foregoing functions. The computer, for example, includes at least one processor and at least one computer-readable storage medium storing the program. An object of the present invention can be achieved by the processor of the computer reading and executing the program stored in the storage medium. Examples of the processor encompass a central processing unit (CPU). Examples of the storage medium encompass a “non-transitory tangible medium” such as a read only memory (ROM), a tape, a disk, a card, a semiconductor memory, and a programmable logic circuit. The computer may further include a random access memory (RAM) or the like in which the program is loaded. Further, the program may be supplied to the computer via any transmission medium (such as a communication network and a broadcast wave) which allows the program to be transmitted. Note that an aspect of the present invention can also be achieved in the form of a computer data signal in which the program is embodied via electronic transmission and which is embedded in a carrier wave.

The present invention is not limited to the embodiments, but can be altered by a skilled person in the art within the scope of the claims. The present invention also encompasses, in its technical scope, any embodiment derived by combining technical means disclosed in differing embodiments.

### Examples

An Example of the present invention will be described below.

The opening detection sheets 10 having different dry weights per unit area of the first resin layer 13 were prepared, and the amount of insulating resin required for the first resin layer 13 to function as an insulating layer was examined. Table 1 shows the results of evaluation of the insulation performance of the opening detection sheets 10 having different dry weights per unit area of the first resin layer 13.

Note that an aluminum foil was used for the metal foil layer 12, the third resin layer 11 was formed on the matte surface side of the aluminum foil, and the first resin layer 13 was formed on the bright surface side of the aluminum foil. For the formation of the first resin layer 13, No. 8800NL manufactured by Tanaka Chemical Industries, Ltd. was used.

Further, for each of the prepared opening detection sheets 10, the opening detection sheet 10 and the storage sheet 31 were thermally fused to each other by applying a temperature of 140° C. and a pressure of 0.25 MPa using an M2 machine manufactured by CKD. Note that this thermal fusion treatment is called heat sealing and assumes the temperature and pressure applied in the heat sealing treatment.

In the determination of the insulation property of the first resin layer 13, the first resin layer 13 was evaluated as “good” when a resistance value of the opening detection sheet 10 (measured at points 10 mm away from each other on the first resin layer) measured by a tester (maximum measured resistance value of 40 MΩ) was greater than the maximum measured resistance value, and was evaluated as “no good” when the resistance value was less than the maximum measured resistance value. The determination of the insulation property was carried out before the heat sealing and after the heat sealing.

TABLE 1

| | Insulation | Insulation |
|---|---|---|
| Application | performance | performance |
| amount | (before heat | (after heat |
| (g/m²) | sealing) | sealing) |
| 0.44 | No good | — |
| 0.98 | Good | No good |
| 1.10 | Good | No good |
| 1.36 | Good | — |
| 1.48 | Good | Good |
| 1.96 | Good | — |
| 2.01 | Good | Good |
| 2.24 | Good | Good |
| 2.62 | Good | — |
| 3.00 | Good | — |
| 3.70 | Good | Good |
| 4.11 | Good | — |

According to the results shown in Table 1, when the dry weight per unit area of the first resin layer 13 was not less than 1.48 g/m², the first resin layer 13 functioned as an insulating layer even after the heat sealing treatment.

In a case where the step of applying the insulating resin to form the first resin layer 13 is performed by an apparatus, the amount of resin that can be applied in a single step depends on an apparatus used. Thus, to apply the insulating resin thickly using the apparatus, it is necessary to use an apparatus which is capable of applying a large amount of resin in a single step or to perform the application multiple times (i.e., to give several coats). To make the dry weight per unit area of the first resin layer 13 higher than 3.70 g/m², the step of applying the insulating resin may have to be performed three or more times. Accordingly, it is desirable that the dry weight per unit area of the first resin layer 13 is not more than 3.70 g/m².

Aspects of the present invention can also be expressed as follows:

An opening detection sheet (10) in accordance with an aspect of the present invention includes: a metal foil layer (12) being made of a metal containing aluminum; a first resin layer (13) having an insulation property; a circuit pattern (14) being printed with use of an ink containing a conductive substance; and a second resin layer (15) covering at least a part of the circuit pattern (14), wherein the metal foil layer (12), the first resin layer (13), the circuit pattern (14), and the second resin layer (15) are stacked in this order.

According to the above configuration, the circuit pattern (14) is formed by printing with use of an ink containing a conductive substance. As a result, it is possible to form the circuit pattern (14) without performing etching, which requires a large number of steps and involves an inevitable significant increase in cost, and without using a metal paste such as a silver paste. Thus, it is possible to reduce the number of steps for producing the opening detection sheet (10).

The opening detection sheet (10) may be configured such that a detection target area (5) is set in the opening detection sheet (10), and the circuit pattern (14) is arranged such that, when the opening detection sheet (10) is broken in the detection target area (5), the circuit pattern (14) is broken.

According to the above configuration, when the opening detection sheet (10) is broken, the circuit pattern (14) is broken. That is, before and after the opening detection sheet (10) is broken, a change occurs on the electrical signal in the circuit pattern (14). For example, by employing such an opening detection sheet (10) in the packaging material (100), it is possible to realize a packaging material (100) having an opening detection function of detecting whether or not the opening detection sheet (10) in the detection target area (5) has been broken on the basis of a change in current value detected upon application of a predetermined voltage to the circuit pattern (14).

The opening detection sheet (10) may be configured such that the circuit pattern (14) has a connecting section (16) in a part which is not covered by the second resin layer (15) so that a voltage is applied to the circuit pattern (14) via the connecting section (16).

By employing such an opening detection sheet (10) in the packaging material (100), it is possible to realize the packaging material (100) having the opening detection function of detecting the electrical signal of the circuit pattern (14) via the connecting section (16). For example, it is possible to prevent the broken circuit pattern (14) from being electrically conducted again, by covering a broken surface with the resin used for the second resin layer (15). Further, in the second region of the circuit pattern (14), an electrical connection can be provided since the circuit pattern (14) is exposed in the second region.

The first resin layer (13) may be formed by applying an insulating resin onto the metal foil layer (12).

The dry weight per unit area of the first resin layer (13) may be not less than 1.48 g/m² and not more than 3.70 g/m².

The ink may contain carbon nanotubes as the conductive substance.

It is known that a conductive ink in which carbon nanotubes are contained has improved electrical conduction property. The electrical conductivity of the circuit pattern (14) can be adjusted by adjusting the amount of carbon nanotubes contained in the ink for use in printing of the circuit pattern (14).

The second resin layer (15) may be formed by applying a resin onto the first resin layer (13).

The opening detection sheet (10) may further include a third resin layer (11) having thermal fusibility and being stacked on a surface facing away from the first resin layer (13).

According to the above configuration, it is possible to easily attach the opening detection sheet (10) to a detection target by thermal fusion.

A packaging material (100) in accordance with an aspect of the present invention may be a packaging material (100) configured to include: the above-described opening detection sheet (10); and a storing part (32) that stores a stored object (33), wherein breaking the opening detection sheet (10) allows the stored object (33) to be taken out from the storing part (32).

This makes it possible to realize the packaging material (100) having the function of detecting that the stored object (33) has been taken out.

The packaging material (100) may be configured such that the packaging material (100) has one or more recesses each constituting the storing part (32) which is one of storing parts (32), and an opening of each of the recesses is sealed with the opening detection sheet (10).

The packaging material (100) may be configured such that the circuit pattern (14) of the opening detection sheet (10) has separate parts corresponding one-to-one to the storing parts (32), and the separate parts are not electrically conductive with each other.

This makes it possible to realize the packaging material (100) having the function of detecting from which storing part (32) of the packaging material (100) the stored object (33) has been taken out.

An opening detection device (20, 20a) in accordance with an aspect of the present invention is an opening detection device (20, 20a) for detecting that the storing part (32) has been opened, the opening detection device (20, 20a) including: a terminal section (29) being electrically connectable to a circuit pattern (14) included in an opening detection sheet (10); and an opening detection processing section (22, 22a) that detects breakage of the circuit pattern (14) on a basis of a change having occurred on an electrical signal in the circuit pattern (14).

When the opening detection sheet (10) is broken, the circuit pattern (14) is broken. According to the above configuration, the opening detection device (20, 20a) detects breakage of the circuit pattern (14) on the basis of a change having occurred on the electrical signal in the circuit pattern (14). This allows the opening detection device (20, 20a) to detect that the storing part (32) which stores the stored object (33) in the packaging material (100) has been opened.

The opening detection device (20, 20a) may be configured such that, in a case where the opening detection processing section (22, 22a) detects that the circuit pattern (14) has been broken, the opening detection processing section (22, 22a) outputs, for each of the storing parts (32), information indicating that the corresponding one of the storing parts (32) where the circuit pattern (14) is arranged has been opened.

The above configuration allows the opening detection device (20, 20a) to output information indicating that the storing part (32) has been opened. This allows the user to check the opening status of each storing part (32).

The opening detection device (20a) may further include a communication section (27) that transmits, to an external device (50), information indicating that the storing part (32) corresponding to the broken circuit pattern (14) being printed has been opened.

The above configuration allows the opening detection device (20, 20a) to cause the external device (50) to output the information indicating that the storing part has been opened. Here, the external device (50) is desirably an electronic device that includes the display section (54) which displays the information indicating that the storing part (32) has been opened. More specifically, the external device (50) includes a smartphone, a mobile phone, a tablet terminal, and the like. Note that the opening detection device (20a) and the external device (50) may be connected by wire or may be connected wirelessly. For the wireless connection, for example, Bluetooth (registered trademark) may be used.

The opening detection device (20, 20a) in accordance with each aspect of the present invention may be realized by a computer. In this case, the computer is operated based on a control program for causing the computer to realize the opening detection device (20, 20a) by causing the computer to operate as each section (software element) of the opening detection device (20, 20a), and (ii) a computer-readable storage medium in which the program is stored. Such a control program and a computer-readable storage medium are also encompassed in the scope of the present invention.

A method for producing the opening detection sheet (10) in accordance with an aspect of the present invention includes: a first resin applying step (step S1) of applying a first resin having an insulation property onto a metal foil layer (12) being made of a metal containing aluminum to form a first resin layer (13); a circuit pattern (14) printing step (step S2) of printing, on the first resin layer (13), a circuit pattern (14) with use of an ink containing a conductive substance; and a second resin applying step (step S3) of applying a second resin so as to cover at least a part of the circuit pattern (14) to form a second resin layer (15).

According to the above configuration, the first resin layer (13), the circuit pattern (14), and the second resin layer (15) are formed by the same method. The opening detection sheet (10) produced by such a method can achieve a lower capital investment cost and lower energy consumption, and thus achieves a lower production cost, as compared with the one produced by etching or the like. Therefore, by employing the opening detection sheet (10) produced by such a method, it is possible to provide a packaging material (100) having an opening detection function at a lower cost.

### EXPLANATION OF SIGNS

5 detection target area
10 opening detection sheet
11 third resin layer
12 metal foil layer
13 first resin layer
14 circuit pattern
15 second resin layer
16 connecting section
20, 20a opening detection device
22, 22a opening detection processing section
25 display section
29 terminal sections
31 storage sheet
32 storing part
33 stored object
50 external devices
51 control section
54 display section
100 packaging material
S1 first resin applying step
S2 circuit pattern printing step
S3 second resin applying step

1. A method for producing an opening detection sheet, comprising:
a first resin applying step of applying, using gravure printing, a first resin having an insulation property onto a metal foil layer made of a metal containing aluminum to form a first resin layer;
a circuit pattern printing step of printing, using gravure printing, a circuit pattern onto the first resin layer with use of an ink containing a conductive substance; and
a second resin applying step of applying, using gravure printing, a second resin onto the first resin layer so as to cover at least a part of the circuit pattern to form a second resin layer,
said method further comprising a step of applying, using gravure printing, a third resin onto a surface of the metal foil layer that faces away from the first resin layer to form a third resin layer having thermal fusibility,
wherein the gravure printing comprises:
(1) a step of immersing a part of a gravure printing cylinder provided with recesses on a plate surface thereof in a resin reservoir in which the first resin, the second resin, the ink, or the third resin is reserved, so that the recesses are filled with the first resin, the second resin, the ink, or the third resin;
(2) a step of lifting the gravure printing cylinder from the resin reservoir while rotating the gravure printing cylinder;
(3) a step of removing, with a blade, the resin adhering to areas other than the recesses on the plate surface of the gravure printing cylinder;
(4) a step of passing the metal foil between a pressure roller and the gravure printing cylinder, so that the resin in the recesses is transferred to the metal foil; and
(5) a step of drying the resin transferred to the metal foil,
wherein a dry weight per unit area of the first resin layer is not less than 1.48 g/m² and not more than 3.70 g/m²,
wherein the first resin contains, as a main component, at least one of vinyl chloride and vinyl acetate, and
wherein a dry weight per unit area of the second resin layer is not less than 0.8 g/m² and not more than 2.0 g/m².

2. An opening detection sheet produced by the method of claim 1, said opening detection sheet comprising:
a metal foil layer being made of a metal containing aluminum;
a first resin layer having an insulation property;
a circuit pattern made of an ink containing a conductive substance; and
a second resin layer covering at least a part of the circuit pattern,
wherein the metal foil layer, the first resin layer, the circuit pattern, and the second resin layer are stacked in this order,
wherein said opening detection sheet further comprises a third resin layer having thermal fusibility and being stacked on a surface of the metal foil layer which surface faces away from the first resin layer,
wherein a dry weight per unit area of the first resin layer is not less than 1.48 g/m² and not more than 3.70 g/m²,
wherein the first resin contains, as a main component, at least one of vinyl chloride and vinyl acetate, and
wherein a dry weight per unit area of the second resin layer is not less than 0.8 g/m² and not more than 2.0 g/m².

3. The opening detection sheet according to claim 2, wherein a detection target area is set in said opening detection sheet, and the circuit pattern is arranged such that, when the opening detection sheet is broken in the detection target area, the circuit pattern is broken.

4. The opening detection sheet according to claim 2, wherein the circuit pattern has a connecting section in a part which is not covered by the second resin layer so that a voltage is applied to the circuit pattern via the connecting section.

5. The opening detection sheet according to claim 2, wherein the ink contains carbon nanotubes as the conductive substance.

6. A packaging material comprising:
the opening detection sheet according to claim 2; and
a storing part that stores a stored object,
wherein breaking the opening detection sheet allows the stored object to be taken out from the storing part.

7. The packaging material according to claim 6, wherein said packaging material has one or more recesses each constituting the storing part which is one of storing parts, and an opening of each of the recesses is sealed with the opening detection sheet.

8. The packaging material according to claim 6, wherein the circuit pattern of the opening detection sheet has separate parts corresponding one-to-one to the storing parts, and the separate parts are not electrically conductive with each other.
